(19) United States
(12) Patent Application Publication
(10) Pub. No.: US 2019/0203342 A1
(43) Pub. Date: Jul. 4, 2019

(54) COOLING SYSTEM AND EVAPORATION MACHINE

(71) Applicant: Wuhan China Star Optoelectronics Semiconductor Display Technology Co., Ltd., Wuhan (CN)

(72) Inventor: Chunlai SONG, Shenzhen (CN)

(21) Appl. No.: 15/997,894

(22) Filed: Jun. 5, 2018

Related U.S. Application Data
(63) Continuation of application No. PCT/CN2018/072614, filed on Jan. 15, 2018.

(30) Foreign Application Priority Data
Dec. 29, 2017 (CN) 201711473336.X

(51) Int. Cl. C23C 14/24; C23C 14/12; H01L 51/00; C23C 14/54; H01L 51/56

(52) U.S. Cl. CPC C23C 14/24; C23C 14/12; H01L 51/56; C23C 14/54; H01L 51/001

(57) ABSTRACT

A cooling plate for a cooling system includes a plurality of cooling zones providing with a water loop. A water temperature controller for regulating a temperature of water stored in the water storage tank for delivering water to a water inlet and recovering water from a water outlet. The plurality of cooling temperature of the water flowing in the water loop in the zone is different. By the above mentioned structure, the plurality of water loops are supplied with water from a water storage tank, the temperature controller adjusts the temperature of the water in the water storage tank such that the temperature of the water is different, so that the temperature of each part of the glass substrate is adjusted by the water loop of multiple cooling zones on the cooling plate to ensure uniform heating of the glass substrate.

### RELATED APPLICATIONS

This application is a continuation application of PCT Patent Application No. PCT/CN2018/072614, filed Jan. 15, 2018, which claims the priority benefit of Chinese Patent Application No. 201711473336.X, filed Dec. 29, 2017, which is herein incorporated by reference in its entirety.

### FIELD OF THE DISCLOSURE

The present disclosure belongs to the field of OLED manufacturing technology, and more particularly relates to a cooling system and a vapor deposition machine.

### BACKGROUND

Cooling plates for OLED evaporation machines have the main two function: first, the glass substrate back against the flat cooling plate surface is used for evaporation with supporting function; second, through the cooling plate cooling, the temperature of the vapor-deposited glass substrate is controlled by the water loop, and the heat carried by the vapor-deposition material that is not evaporated by the vapor deposition source causes the glass substrate to be heated and deformed, resulting in the positional deviation of the vapor-deposited film.

The cooling water loop of the existing cooling plate is a water loop which is arranged on the cooling plate in an entire surface and only has one water inlet and a water outlet, which is consistent with the temperature control. The temperature on the glass substrate is changed by the evaporation material. The relative position is different, there are differences, uneven. The overall temperature control cannot be uneven on the heat to make the corresponding adjustment of different locations.

Therefore, there is a need to provide a new cooling system that solves the above technical problems to improve the yield of the deposited film.

### SUMMARY

The object of the present application is to provide a cooling system capable of controlling the temperature regionally and improving the yield of the deposited film.

For the purpose of the present application, the present application provides the following technical solutions:

According to a first aspect, a cooling system includes a cooling plate, a water storage tank, and a temperature controller. The cooling plate includes a plurality of cooling zones, and each of the cooling zones is provided with a water loop. The water loop includes a water inlet and a water outlet. A water outlet for adjusting a temperature of water stored in the water storage tank, the water storage tank is configured to deliver water to the water inlet and recover water from the water outlet, and the temperature of the water flowing in the water loop of the cooling zone is different.

In a first possible implementation manner of the first aspect, the cooling plate includes a first long side and a second long side opposite to each other, and a first short side and a second short side opposite to each other, and a plurality of the cooling zones including a first cooling zone, a second cooling zone and a third cooling zone, the first cooling zone is disposed near the first short side, the third cooling zone is disposed near the second short side, and the second cooling zone is provided between the first cooling zone and the third cooling zone.

With reference to the first aspect and the first possible implementation manner of the first aspect, in a second possible implementation manner of the first aspect, the water loop comprises a first water loop, a second water loop, and a third water loop, the first water loop is disposed in the first cooling zone, the water inlet and the water outlet of the first water loop are disposed on the first short side.

With reference to the first aspect and the first possible implementation manner of the first aspect, in a third possible implementation manner of the first aspect the second water loop is disposed in the second cooling zone, and the water inlet and the water outlet of the second water loop are disposed on the first long side and/or the second long side.

With reference to the first aspect and the first possible implementation manner of the first aspect, in a fourth possible implementation manner of the first aspect, the water loop of the first cooling zone comprises a fourth water loop, a fifth water loop, and a sixth water loop, the fourth water loop, the fifth water loop and the sixth water loop are arranged sequentially along the first short side direction and cover the first cooling zone, the water inlet and the water outlet of the fourth water loop, the fifth water loop and the sixth water loop are disposed on the first short side.

With reference to the first aspect and the first possible implementation manner of the first aspect, in a fifth possible implementation manner of the first aspect, the water loop of the second cooling zone comprises a seventh water loop, an eighth water loop and a ninth water loop arranged sequentially along the first long side toward the second long side, the seventh water loop, the eighth water loop and the ninth water loop are covered with the second cooling zone, and the water inlet and the water outlet of the seventh water loop are provided on the first long side and the water inlet of the eighth water loop is provided on the first long side, the water outlet of the eighth water loop is provided on the second long side, and the water inlet and the water outlet of the ninth water loop are disposed on the second long side.

With reference to the first aspect and the first possible implementation manner of the first aspect, in a sixth possible implementation manner of the first aspect, the water loop comprises main cooling sections extending along the first long side direction and transition sections connecting two adjacent main cooling sections, the transition section extend along the first short side direction, and a separating distance between two of the adjacent main cooling sections is equal.

With reference to the first aspect and the sixth possible implementation manner of the first aspect, in a seventh possible implementation manner of the first aspect, distances of the transition sections of the water loops between the adjacent first and second cooling zones and between the adjacent second cooling zone and the third cooling zone are equal.

With reference to the first aspect and the seventh possible implementation manner of the first aspect, in an eighth possible implementation manner of the first aspect, the distance of the transition section of the water loop between the adjacent first second cooling zones is equal to the separating distance between two of the adjacent main cooling sections.

In a second aspect, the present application further provides an evaporation machine, including the cooling system of the various implementations of the first aspect.

### Beneficial Effects of the Present Disclosure

The present invention provides a cooling system, wherein the cooling plate is divided into a plurality of cooling zones, and a plurality of cooling zones are respectively provided with water loops. The plurality of water loops are supplied with water from a water storage tank. The thermostat adjusts water so the temperature of the water in the plurality of water loops is different. During the OLED evaporation process, the temperature of each part on the glass substrate is adjusted by the water loop of the plurality of cooling zones on the cooling plate to ensure uniform heating of the glass substrate, and improve the deposition rate of the deposited film.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a schematic diagram of a cooling system according to one embodiment of the present application, with the water loop omitted;

FIG. 2 is a schematic structural view of an embodiment of the cooling plate;

FIG. 3 is a schematic structural view of another embodiment of the cooling plate;

FIG. 4 is a schematic structural view of an embodiment of the cooling plate and the water loop;

FIG. 5 is a schematic structural view of another embodiment of the cooling plate and the water loop;

FIG. 6 is a schematic diagram of another embodiment of the cooling plate and the water loop.

### DETAILED DESCRIPTION OF PREFERRED EMBODIMENTS

The technical solutions in the embodiments of the present invention will be described clearly and completely hereinafter with reference to the accompanying drawings. Apparently, the described embodiments are merely a part but not all embodiments of the present invention. All other embodiments obtained by a person of ordinary skill in the art based on the embodiments of the present application without creative efforts shall fall in the protection scope of this application.

The embodiment of the present disclosure provides an evaporation machine, which includes a cooling system for cooling glass substrates at different temperatures in different zones.

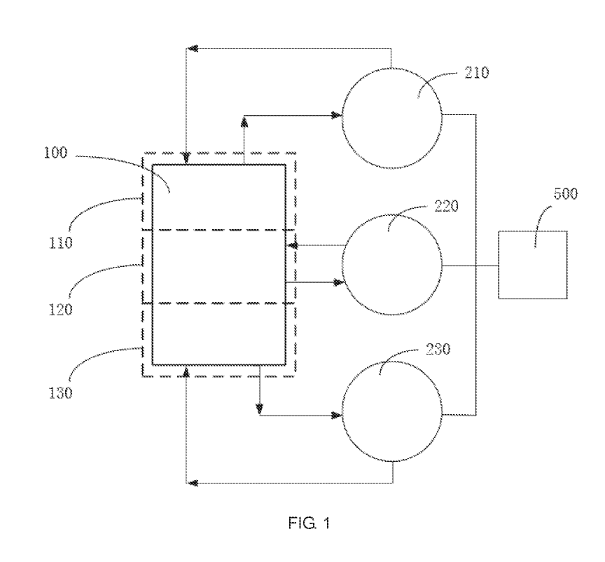

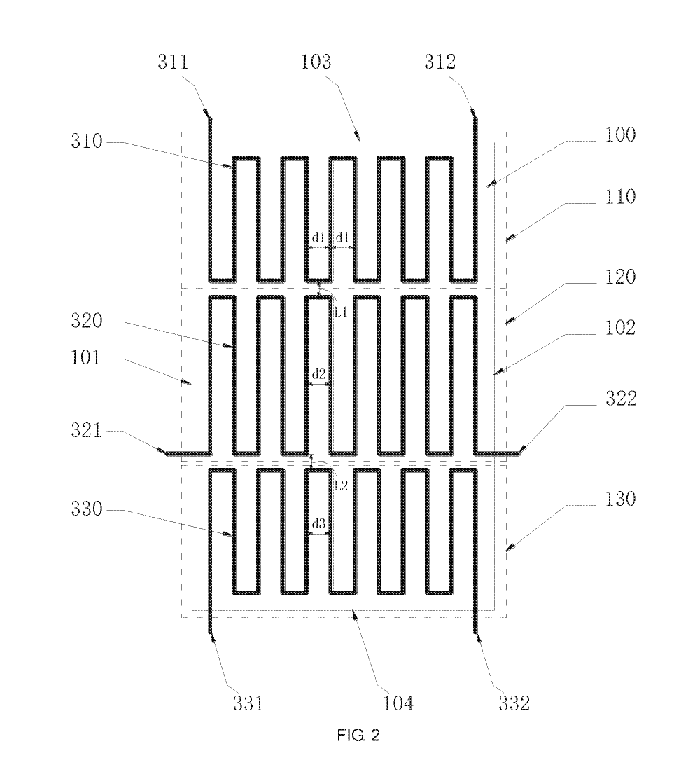

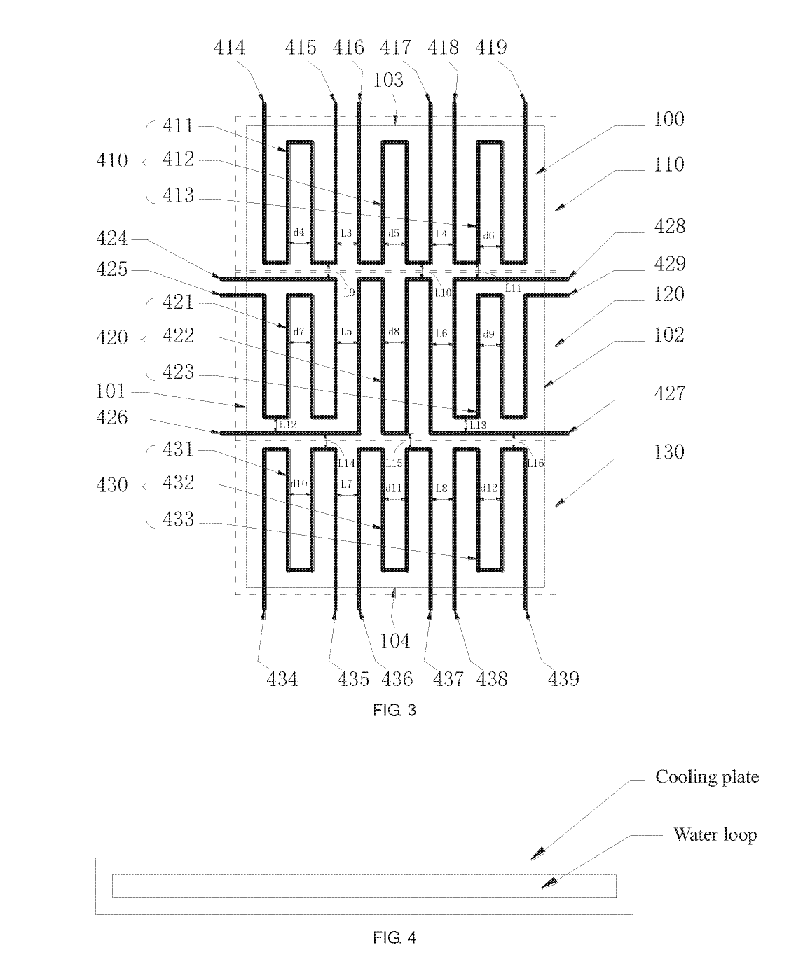

Please refer to FIG. 1 to FIG. 3. FIG. 1 is a schematic view of a cooling system of the present disclosure of the embodiment, not shown the water loop, FIG. 2 is a schematic view of an embodiment of a cooling plate, and FIG. 3 is another schematic configuration of the cooling plate according to the embodiment. The present embodiment provides a cooling system includes a cooling plate 100, and the cooling plate includes a first long side 101 and a second long side 102 opposite to the first long side 101, a first short side 103 and a second short side 104 opposite to the first short side 103. The first short side 103 and the second short side 104 are connected between the first long side 101 and the second long side 102. The cooling plate 100 may have a rectangular shape.

The cooling plate 100 includes a plurality of cooling regions. In an embodiment, a plurality of the cooling regions has the same zone.

In an implementation manner, the multiple cooling regions include a first cooling region 110, a second cooling region 120 and a third cooling region 130, the first cooling region 110 is disposed near the first short side 103, and the third cooling zone 130 is disposed near the second short side 104, and the second cooling zone 120 is disposed between the first cooling zone 110 and the third cooling zone 130.

Specifically, the first zone 110 occupies by a cooling area of the cooling plate 100 extending from the first short side 103 toward the middle of the cooling plate 100. The extending direction is in the direction of the first long side 110, a third cooling zone 130 occupies by a cooling area of the cooling plate 100 from the third short side 130 extending toward the middle of the cooling plate 100 extends along a direction of the first long side 110. The second cooling zone 120 occupies an area between the first cooling zone 110 and the third cooling zone 130. The first cooling zone 110, the second cooling zone 120, and the third cooling zone 130 are continuous three zones connecting to each other. In one embodiment, area of the first cooling zone 110, the second cooling zone 120, and the third cooling zone 130 are the same. Further, the first cooling zone 110, the second cooling zone 120 and the third cooling zone 130 are rectangular, and the three partitions the cooling plate 100 into three zones of the same zone, each zone has a cooling area is one-third of the total zone of the cooling plate 100.

Further, a plurality of the cooling zones is respectively provided with a water loop, and the water loop comprises a water inlet and a water outlet. Preferably, the water loop is arranged in a serpentine shape within the cooling zone. The cooling system further includes a water storage tank 210 and a controller 500. The temperature controller 500 for the temperature of the water stored in the water storage tank 210 adjustment. The water storage tank 210 for feeding to the water is supplied through the water inlet, and water is recovered from the water outlet, and temperature of water flowing through the water loop in the plurality of cooling zones is different. The water inlet and outlet are used respectively for inputting and outputting water, and cooling water flows in the water loop, and absorbs the heat of the water loop of the glass substrate the cooling water, and the water flows away the heat. The water loop in a serpentine arrangement covers more zone and allows the water loops to be evenly arranged in the various parts of the cooling zone, and the heat can be absorbed and removed by the evenly arranged water loop. The water storage tank 210 may include a plurality of water storage zones with different temperatures. The different temperature of the water in the water storage zones is adjusted by the temperature controller 500. The water storage tank 210 may also be a plurality of similar water storage tanks. For example, a water storage tank 220, a water storage tank 230 and the like. Each water storage tank corresponds to one cooling water loop so that the water temperature of each cooling water loop is different, and temperature control in different regions of the glass substrate may be performed.

The heat of the glass substrate may also be transmitted to the cooling plate 100 first, and then the heat of the cooling plate 100 is transmitted to the water loop, so that the heat of the glass substrate may also be carried away.

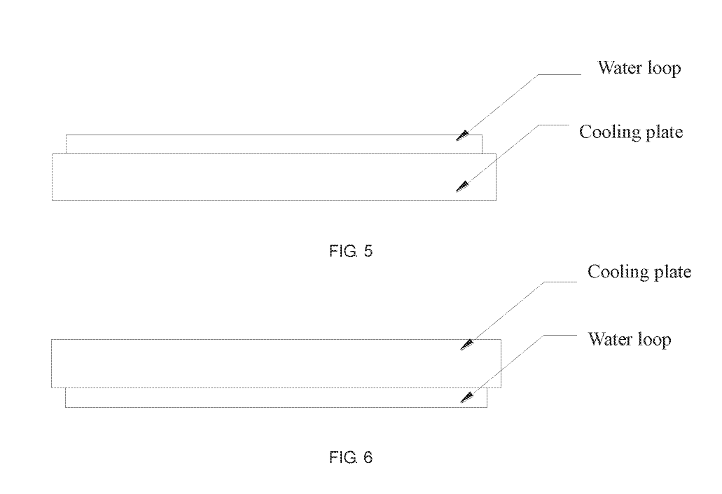

Please refer to FIG. 4 to FIG. 6. FIG. 4 is a schematic view of one embodiment of a cooling plate and the water loop. FIG. 5 is a schematic structural diagram of another embodiment of the cooling plate and the water loop. FIG. 6 is a schematic structural diagram of another embodiment of the cooling plate and the water loop. The cooling plate 100 includes opposite upper and lower surfaces, and the upper surface is used for supporting a glass substrate (not shown), the water loop may be disposed in the cooling plate (as shown in FIG. 3), or on the upper surface of the cooling plate (As shown in FIG. 4), or the lower surface of the cooling plate (as shown in FIG. 5). When the water loop is disposed on the upper surface of the cooling plate, the water loop forms a supporting plane. When the water loop is set on the upper surface or the lower surface of the cooling plate, the water loop can be made of a pipe. The pipe is fixed on the upper surface or the lower surface of the cooling plate through welding or gluing processes. The pipe should have good heat dissipation performance, for example, steel or aluminum and other metal materials. The cross-section of pipes can be circular, and it can be rectangular. When the water loop is set in the cooling plate, the water loop can be a channel dug in the cooling plate. The cooling plate can be a two-layer structure. The internal water loop is obtained by dug grooves on the surfaces of the two cooling plates respectively. The two layers of the cooling plate made into one. In other embodiment, the water loop may also be grooved in the upper surface of the cooling plate. The cooling plate is placed on a workbench (not shown in the figure) or erected on a bracket (not shown in the figure). The cooling plate is usually placed horizontally so that the glass substrate supported by the cooling plate is in a horizontal position for facilitating the evaporation of the OLED Process steam acts on the glass substrate.

By dividing the cooling plate 100 into a plurality of cooling zones and providing water loops in each of the cooling zones, the plurality of water loops are supplied with water from the water storage tank, and the temperature controller adjusts the temperature of the water in the water storage tank so that the plurality of water loops have different temperature during the OLED evaporation process. The temperature of each part of the glass substrate is adjusted by the water loop of the cooling zones on the cooling plate 100 to ensure uniform heating of the glass substrate and to improve the yield of the deposited film.

Referring to FIG. 2, in one embodiment, the water loop comprises the first water loop 310, the second water loop 320 and the third water loop 330. The first water loop 310 is provided in the first cooling zone 110. The water inlet 311 and the water outlet 312 of the first water loop 310 are disposed on the first short side 103. In other embodiments, the water inlet 311 of the first water loop 310 may be disposed on the first long side 101, and the water outlet 312 of the first water loop 310 may be disposed on the second long side 102. The water inlet 311 and the water outlet 312 of the first water loop 310 are arranged at different positions to change the temperature of the edge portion of the cooling plate 100. Preferably, the water inlet 311 and the water outlet 312 of the first water loop 310 are symmetrically disposed. The temperature change at the edge of the cooling plate 100 is relatively small, so that the difference in the temperature transmitted to the glass substrate is reduced to adversely affect the temperature. The symmetrical arrangement of the water inlet and the water outlet is also a preferred embodiment of the other embodiments in this disclosure.

The water inlet 311 and the water outlet 312 of the first water loop 310 are connected to a cooling water conveying pipe (not shown in the figure). In each embodiment of the present application, the water inlet and the water outlet of each of the cooling water connect to the different water pipes in order to achieve independent control of the temperature of different water loops.

The second water loop 320 is disposed in the second cooling zone 120, and the water inlet 321 of the second water loop 320 is disposed on the first long side 101 and the water outlet 322 of the second water loop 320 is disposed on the second long side 102. In other embodiments, the water inlet 321 and the water outlet 322 of the second water loop 320 may also be disposed on the first long side 101 or the second long side 102 simultaneously.

The third water loop 330 may be disposed in a similar manner to the first water loop 310 except that the water inlet 331 and the water outlet 332 of the third water loop 330 are disposed on the second short side 104. In a preferred embodiment, the first water loop 310 and the third water loop 330 have a symmetrical structure.

The first water loop 310 includes main cooling sections extending in the direction of the first long side 101 and transition sections connecting adjacent two of the main cooling sections. The transition section extends along the first short side 103, and the adjacent main cooling sections are equally spaced apart (as shown by d1 in FIG. 1). The length of the main cooling section is greater than the length of the transition section and in some embodiments the length of the main transition section is 2 to 10 times of the length of the transition section. The main cooling sections and the transition section are interconnected to form a serpentine shape of the first water loop 310 and are uniformly arranged within the first cooling zone 110. Specifically, the main cooling section which the water inlet 311 of the first water loop 310 is connected to is located at the edge of the first cooling zone 110. The main cooling section is near the first long side 101 and parallel with the first long side 101. The main cooling section connected to the water outlet 312 of the first water loop is located at the edge of the other side of the first cooling zone 110 near the second long side 102 and parallel with the second long side 102. The main cooling sections connect with the water inlet 311 of the first water loop 110. The main cooling sections connect with other main cooing section by the transition section, such that the first water loop 310 forms a whole loop from inlet 310 to outlet 312 and form a serpentine shape.

The structure of the second water loop 320 is similar to the structure of the first water loop 310 and also includes a main cooling section extending in the direction of the first long side 101 and a transition section connecting two adjacent main cooling sections. The transition section extends in the direction of the first short side 103, and the intervals between the adjacent main cooling sections are equal (as shown by d2 in FIG. 1). The structure of the third water loop 330 is also similar to the structure of the first water loop 310, and also includes a main cooling section extending in the direction of the first long side 101 and a transition section connecting two adjacent main cooling sections. The transition section extends in the direction of the first short side 103, and the intervals between the adjacent main cooling sections are equal (as shown by d3 in FIG. 1).

Further, the distance d1 between the adjacent main cooling section of the first water loop 310, a third distance d2 between the adjacent main cooling sections 330 of the second water loop 320, the distances d3 between the adjacent main cooling sections of the second water loop 330 are equal so that the temperature changes of the respective slits inside the water loop of the first cooling zone 110, the second cooling zone 120, and the third cooling zone 130 are the same.

Further, the distance of the transition sections of the water loops between the adjacent first cooling zone 110 and the second cooling zone 120 and the distance of the transition section of the water loop between the adjacent second cooling zone 120 and the third cooling zone 130 are equal. Specifically, the distance between the transition section of the first water loop 310 of the first cooling zone 110 and the transition section of the second water loop 320 of the second cooling region 120 is L1, and distance between the transition section of the second water loop 320 of the second cooling zone 120 and the transition section of the third water loop 330 of the third cooling zone 130 is L2, and L1 is equal to L2. The settings are such that the temperature changes in the gaps between the water loops arranged between the adjacent first, second and third cooling zones 110, 120 and 130 on the cooling plate 100 are the same.

Further, the distance between the transition sections of the water loops of the adjacent first cooling zone 110 and the second cooling zone 120 is equal to the separation distance between the adjacent main cooling sections. Specifically, the distance L1 between the transition section of the first water loop 310 and the transition section of the second water loop 320 is equal to the separation distance d1 between the adjacent main cooling sections of the first water loop 310. Preferably, L1 is equal to d2 and d3. With the above arrangement, the water loop covers uniformly the cooling plate 100 adjacent to the first cooling zone 110, the second cooling zone 120 and the third cooling zone 130 to enhance the cooling effect on the glass substrate.

Referring to FIG. 3, in another embodiment, the water loop 410 of the first cooling zone 110 includes a fourth water loop 411, a fifth water loop 412 and a sixth water loop 413, and the fourth water loop 411, the fifth water loop 412 and the sixth water loop 413 are continuously arranged along the direction of the first short side 103 and cover the first cooling zone 110. The water inlet and outlet of the fourth water loop 411, the fifth water loop 412 and the sixth water loop 413 are disposed on the first short side 103. Specifically, the water loop provided in the first cooling region 110 in this embodiment is basically the same as the previous embodiment, except that the fourth water loop 411 is provided with a water inlet 414 and a water outlet 415, respectively. The fifth water loop 412 is provided with a water inlet 416 and a water outlet 417, respectively. The sixth water loop 413 is provided with a water inlet 418 and a water outlet 419 respectively. That is to say, in this embodiment, the space of the first cooling zone 110 is divided into 3 water loops to control the temperature so that the temperature control in the first cooling zone 110 is finer.

Further, the water loop 420 of the second cooling zone 120 includes a seventh water loop 421, an eighth water loop 422 and a ninth water loop 423 that are sequentially arranged along the first long side 101 toward the direction of the second long side 102. The seventh water loop 421, the eighth water loop 422 and the ninth water loop 423 cover the second cooling zone 120. The water inlet 424 and the water outlet 425 of the seventh water loop 421 425 is disposed on the first long side 101. The water inlet 426 of the eighth water loop 422 is disposed on the first long side 101, and the water outlet 427 of the eighth water loop 422 is disposed on the second long side 102. The water inlet 428 and the water outlet 429 of the ninth water loop 423 are disposed on the second long side 102.

Specifically, the water inlet 424 of the seventh water loop 421 is disposed closer to the first cooling zone 110, and the water outlet 425 of the seventh water loop 421 has offset away from the first short side 103. The structure of the ninth water loop 423 is similar to the structure of the seventh water loop 421 and corresponds to a structure symmetrical about the midpoint of the first short side 103 and the midpoint of the second short side 104. The water inlet 426 and the water outlet 427 of the eighth water loop 422 are disposed closer to the third cooling zone 130. In order to make the arrangement of the water loop more uniform, the seventh water loop 421 and the ninth water loop 422 may have slightly offset from the direction of the second short side 104 by a distance so as to accommodate the position space of the water inlet 426 and the water outlet 427 of the eighth water loop 422.

Further, the water loop 430 of the third cooling zone 130 is substantially the same as the water loop 410 of the first cooling zone 110. The water loop 430 of the third cooling zone 130 includes the tenth water loop 431, the eleventh water loop 432 and the twelfth water loop 433. The tenth water loop 431, the eleventh water loop 432, and the twelfth water loop 433 are arranged sequentially along the direction of the second short side 104 and covers the third cooling loop 130. The water inlet and the water outlet of the tenth water loop 431, the eleventh water loop 432, the twelfth water loop 433, the tenth water loop 431, the eleventh water loop 432, and the twelve water loop 433 are disposed on the first short side 103. Specifically, the water inlet 434 and the water outlet 435 of the tenth water loop 431 are disposed on the second short side 104. The water inlet 436 and the water outlet 437 of the eleventh water loop 432 are also disposed on the second short side 104. The twelfth water inlet 438 and the water outlet 439 of the water loop 433 are also disposed on the second short side 104. The water loop 410 of the first cooling zone 110 and the water loop 430 of the third cooling zone 130 have a symmetrical structure.

Further, the fourth water loop 411 includes a main cooling section extending along the direction of the first long side 101 and a transition section connecting adjacent two of the main cooling sections. The transition section extends along the first short side 103 and the separating distance d4 between the adjacent main cooling sections is the same. The structure of the fifth water loop 412 and the sixth water loop 413 are similar to one of the fourth water loop 411. The separating distance d5 between the adjacent main cooling sections of the fifth water loop 412 is the same, and the separating distance d6 between the adjacent main cooling sections of the sixth water loop 413 is separated by the separating distance d6 is the same.

The structure of the seventh water loop 421 is similar to the structure of the fourth water loop 411. The separating distances d7 between the adjacent main cooling sections are equal and the eighth water loop 422 and the ninth water loop 423 are similar. The separating distance d8 between adjacent main cooling sections of the water loop 422 is equal and the separating distance d9 between adjacent main cooling sections of the ninth water loop 413 is equal.

The structure of the tenth water loop 431 is also similar to the structure of the fourth water loop 411. The separating distances d10 between the adjacent main cooling sections are equal, and the eleventh water loop 432 and the twelfth water loop 433 are also similar. The separating distance d11 between the adjacent main cooling sections of the eleventh water loop 432 is equal and the separating distance d12 between adjacent main cooling sections of the twelfth water loop 433 is equal.

Further, the separating distance between the adjacent main cooling sections of the fourth water loop 411=the fifth water loop 412 and the sixth water loop 413 in the first cooling zone 110 are equal. Specifically, the distance between he adjacent main cooling section 412 of the fourth water loop 411 and the fifth water loop 412 is L3. The distance between the adjacent main cooling sections of the fifth water loop 423 and the sixth water loop 413 is L4. L3 is equal to L4.

The distances between the adjacent main cooling sections of the seventh water loop 421, the eighth water loop 422, and the ninth water loop 423, n the second cooling zone 120 are equal. Specifically, the distance between the adjacent main cooling section of the seventh water loop 421 and the eighth water loop 422 is L5 and the distance between the adjacent main cooling sections of the eighth water loop 422 and the ninth water loop 422 is L6. L5 is equal to L6.

The distances between the adjacent main cooling sections of the tenth water loop 431, the eleventh water loop 432 and the twelfth water loop 433 in the third cooling zone 130 are equal. Specifically, the distance between the adjacent main cooling sections of the tenth water loop 431 and the eleventh water loop 432 is L7, and the distance of the adjacent main cooling sections of the eleventh water loop 432 and the twelfth water loop 433 is L8. L7 is equal to L8.

Further, the distances of the transition section of the water loops between the adjacent first cooling zone 110 and the second cooling zone 120 and the third cooling zone 130 are equal. Specifically, the distance between the transition sections of the fourth water loop 411 and the seventh water loop 421 is L9. The distance between the transition sections of the fifth water loop 412 and the eighth water loop 422 is L10. The distance of the transition section of the sixth water loop 413 and the ninth water loop 423 is L11. The distance between the transition section of the eighth water loop 422 and the transition section of the tenth water loop 431 is L14. The distance between the transition section of the eighth water loop 422 and the eleventh water loop 432 is L15. The distance from the transition section of the eighth water loop and the twelfth water loop 433 is L16. L9, L10, L11, L14, L15 and L16 which are equal to each other.

Further, the distance between the adjacent transition sections 421 of the seventh water loop 421 and the eighth water loop 422 in the second cooling loop 120 is L12, and the distance of the adjacent transition sections of the eighth water loop 422 and the ninth water loop 423 is L13. And L12 is equal to L13.

Further, the distance between the transition sections of the water loops of the adjacent first cooling zone 110 and the second cooling zone 120 is equal to the separation distance between the adjacent main cooling sections. In particular, in connection with the above, d4, d5, d6, d7, d8, d9, d10, d1, d12, L3, L4, L5, L6, L7, L8, L9, L10, L11, L12, L13, L14, L15 and L16 are equal.

Through the above arrangement, the water loop arrangement of the cooling system provided by the present application can separately control the temperature of different regions so that the temperature of the glass substrate can be effectively controlled, the defects caused by the temperature control of the existing water loop can be solved with enhancing the yield of the coating.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A cooling system, comprising a cooling plate, a water storage tank and a temperature controller, wherein the cooling plate comprises a plurality of cooling zones, each of the cooling zones is provided with a water loop, the water loop comprises a water inlet and a water outlet for adjusting a temperature of water stored in the water storage tank, the water storage tank is configured to deliver water to the water inlet and recover water from the water outlet, and temperature of water flowing in the water loop in each cooling zone is different.

2. The cooling system according to claim 1, wherein the cooling plate comprises a first long side and a second long side opposite to each other, and a first short side and a second short side opposite to each other; the plurality of cooling zones comprise a first cooling zone, a second cooling zone and a third cooling zone, the first cooling zone is disposed near the first short side, the third cooling zone is disposed near the second short side, and the second cooling zone is provided between the first cooling zone and the third cooling zone.

3. The cooling system according to claim 2, wherein the water loop comprises a first water loop, a second water loop, and a third water loop, the first water loop is disposed in the first cooling zone, the water inlet and the water outlet of the first water loop are disposed on the first short side.

4. The cooling system according to claim 3, wherein the second water loop is disposed in the second cooling zone, and the water inlet and the water outlet of the second water loop are disposed on the first long side and/or the second long side.

5. The cooling system according to claim 2, wherein the water loop of the first cooling zone comprises a fourth water loop, a fifth water loop, and a sixth water loop; the fourth water loop, the fifth water loop and the sixth water loop are arranged sequentially along the first short side direction and cover the first cooling zone; the water inlet and the water outlet of the fourth water loop, the fifth water loop and the sixth water loop are disposed on the first short side.

6. The cooling system according to claim 2, wherein the water loop of the second cooling zone comprises a seventh water loop, an eighth water loop and a ninth water loop arranged sequentially along the first long side toward the second long side; the seventh water loop, the eighth water loop and the ninth water loop cover the second cooling zone; and the water inlet and the water outlet of the seventh water loop are provided on the first long side, the water inlet of the eighth water loop is provided on the first long side, the water outlet of the eighth water loop is provided on the second long side, and the water inlet and the water outlet of the ninth water loop are disposed on the second long side.

7. The cooling system according to claim 2, wherein the water loop comprises main cooling sections extending along the first long side direction and transition sections connecting two adjacent main cooling sections, the transition section extend along the first short side direction, and a separating distance between two of the adjacent main cooling sections is equal.

8. The cooling system according to claim 7, wherein distances of the transition sections of the water loops between the adjacent first and second cooling zones and between the adjacent second cooling zone and the third cooling zone are equal.

9. The cooling system according to claim 8, wherein the distance of the transition section of the water loop between the adjacent first second cooling zones is equal to the separating distance between two of the adjacent main cooling sections.

10. A deposition machine, comprising a cooling plate, a water storage tank and a temperature controller, wherein the cooling plate comprises a plurality of cooling zones, each of the cooling zones is provided with a water loop, and the water loop comprises a water inlet and a water outlet, the temperature controller is used for regulating temperature of the water stored in the water storage tank, the water storage tank is configured to deliver water to the water inlet and recover water from the water outlet, and temperature of water flowing in the water loops of the cooling zones are different.

11. The deposition machine according to claim 10, wherein the cooling plate comprises a first long side and a second long side opposite to each other, and a first short side and a second short sides opposite to each other, the plurality of the cooling zones comprises a first cooling zone, a second cooling zone and a third cooling zone, the first cooling zone is disposed near the first short side, the third cooling zone is disposed near the second short side, and the second cooling zone is provided between the first cooling zone and the third cooling zone.

12. The deposition machine according to claim 11, wherein the water loop comprises a first water loop, a second water loop, and a third water loop, the first water loop is disposed in the first cooling zone, the water inlet and the water outlet of the first water loop are disposed on the first short edge.

13. The deposition machine according to claim 12, wherein the second water loop is disposed in the second cooling zone, and the water inlet and the water outlet of the second water loop are disposed on the first long side and/or the second long side.

14. The deposition machine according to claim 11, wherein the water loop of the first cooling zone comprises a fourth water loop, a fifth water loop and a sixth water loop, the fourth water loop, the fifth water loop and the sixth water loop are arranged sequentially along the first short side direction and cover the first cooling zone, the water inlet and the water outlet of the fourth water loop, the fifth water loop and the sixth water loop are disposed on the first short side.

15. The deposition machine according to claim 11, wherein the water loop of the second cooling zone comprises a seventh water loop, an eighth water loop and a ninth water loop arranged sequentially along the first long side and the second long side, the seventh water loop, the eighth water loop and the ninth water loop are covered with the second cooling zone, and the water inlet and the water outlet of the seventh water loop are provided in the first long side and the water inlet of the eighth water loop are disposed on the first long side, the water outlet of the eighth water loop is provided on the second long side, and the water inlet of the ninth water loop the water inlet and the water outlet of the ninth water loop are disposed on the second long side.

16. The deposition machine according to claim 11, wherein the water loop comprises main cooling sections extending in the first long side direction and transition sections connecting two of the adjacent main cooling sections, the transition section extends in the first short side direction, and a separating distance between two of the adjacent main cooling sections are equal.

17. The deposition machine according to claim 16, wherein distances of the transition sections of the water loops between the adjacent first and second cooling zones and between the adjacent second cooling zone and the third cooling zone are equal.

18. The cooling system of claim 17 wherein the distance of the transition section of the water loop between the adjacent first second cooling zones is equal to the separating distance between two of the adjacent main cooling sections.
